(19) United States
(12) Patent Application Publication
(10) Pub. No.: US 2016/0189915 A1
(43) Pub. Date: Jun. 30, 2016

(54) ANTENNA STRUCTURE

(71) Applicant: ELECTRONICS AND TELECOMMUNICATIONS RESEARCH INSTITUTE, DAEJEON (KR)

(72) Inventors: CHEOL HO KIM, DAEJEON (KR); KWANGCHUN LEE, DAEJEON (KR); DONGSEUNG KWON, DAEJEON (KR); BONG HYUK PARK, DAEJEON (KR)

(73) Assignee: ELECTRONICS AND TELECELECTROOMMUNICATIONS RESEARCH INSTITUTE, DAEJEON (KR)

(21) Appl. No.: 14/982,796

(22) Filed: Dec. 29, 2015

(30) Foreign Application Priority Data
Dec. 30, 2014 (KR) 10-2014-0193620
Oct. 19, 2015 (KR) 10-2015-0145563

(51) Int. Cl. H01J 37/147; H01Q 3/44; H01J 37/32; H01Q 1/36

(52) U.S. Cl. CPC H01J 37/147; H01Q 1/364; H01Q 3/44; H01J 37/3211; H01J 37/32174

(57) ABSTRACT

Provided is an antenna structure including a substrate and a driven element, a reflector, and a director, which are disposed on the substrate, and respectively configured to transmit/receive, reflect, and direct an electric wave having a first wavelength. The driven element includes a first area having a first length in a first direction parallel to a top surface of the substrate, and a second area having the first length in the first direction and spaced apart from the first area in the first direction. Each of the first area and the second area is a PIN diode that is formed by doping an upper portion of the substrate.

### CROSS-REFERENCE TO RELATED APPLICATIONS

This U.S. non-provisional patent application claims priority under 35 U.S.C. §119 of Korean Patent Application Nos. 10-2014-0193620, filed on Dec. 30, 2014, and 10-2015-0145563, filed on Oct. 19, 2015, the entire contents of which are hereby incorporated by reference.

### BACKGROUND

The present disclosure herein relates to an antenna structure, and more particularly, to a Yagi-Uda antenna structure.

The present disclosure relates to a Yagi-Uda antenna using a solid state plasma antenna in which a selective area of a solid, especially a semiconductor substrate, becomes a so-called plasma state in which free electrons exist, to serve as free electrons of a metal antenna. The solid state plasma antenna applies electrical or optical stimulation to a desired area of a semiconductor substrate in a dielectric state for ordinary time to make the area into a conductor, and use the conductor as an antenna. When this type of variability is applied to the Yagi-Uda antenna, a beamforming antenna that is capable of electrically adjusting the direction, frequency, gain, and the like of a beam may be realized.

### SUMMARY

The present disclosure provides a Yagi-Uda antenna structure that is formed by directly doping a substrate.

The present disclosure also provides an antenna that is capable of changing a directivity through an activation control unit.

The present disclosure is, however, not limited to the above-described disclosure.

An embodiment of the inventive concept provides an antenna structure including: a substrate; and a driven element, a reflector, and a director, which are disposed on the substrate and respectively configured to transmit/receive, reflect, and direct an electric wave having a first wavelength. The driven element includes a first area having a first length in a first direction parallel to a top surface of the substrate, and a second area having the first length in the first direction and spaced apart from the first area in the first direction. Each of the first area and the second area is at least one PIN diode that is formed by doping an upper portion of the substrate.

In an embodiment, the sum of the length of the first area, the length of the second area, and a distance spaced between the first and second areas may be equal to a half of the first wavelength

In an embodiment, the reflector may be a PIN diode having a second length in the first direction, spaced a first width from the driven element in a second direction perpendicular to the first direction, and disposed parallel to the driven element, and a center of the reflector may be spaced apart from that of the driven element in the second direction.

In an embodiment, the second length may be greater than a half of the first wavelength.

In an embodiment, the director may be a PIN diode having a third length in the first direction, spaced a second width from the driven element in a direction opposite to the second direction, and disposed parallel to the driven element, and a center of the director may be spaced apart from centers of the driven element and the reflector in the direction opposite to the second direction.

In an embodiment, the third length may be equal to or less than a half of the first wavelength.

In an embodiment, the first width may be equal to the second width.

In an embodiment, each of the first width and the second width may be equal to a quarter of the first wavelength.

In an embodiment, the antenna structure may further include a plurality of PIN diodes spaced the second width from the director in the direction opposite to the second direction and each of which has the third length in the first direction. The plurality of PIN diodes may be spaced the second width from each other in the direction opposite to the second direction.

In an embodiment, the plurality of PIN diodes may be three PIN diodes.

In an embodiment, the second width may be equal to a quarter of the first wavelength.

In an embodiment, wherein each of the first area of the driven element, the second area of the driven element, the reflector, and the director may include a plurality of PIN diodes, wherein the plurality of PIN diodes may be connected in series.

In an embodiment of the inventive concept, an antenna structure includes: a substrate; and a plurality of antenna areas provided on the substrate and having directivities different from each other. Each of the antenna areas includes a driven element, a reflector, and a director, which are provided on the substrate and respectively configured to transmit/receive, reflect, and direct an electric wave having a first wavelength. The driven element includes: a first area having a first length in a first direction parallel to a top surface of the substrate; and a second area having the first length in the first direction and spaced from the first area in the first direction. Each of the first area and the second area is at least one PIN diode that is formed by doping an upper portion of the substrate

In an embodiment, the reflector may be the PIN diode having a second length in the first direction, spaced a first width from the driven element in a second direction perpendicular to the first direction, and disposed parallel to the driven element, and a center of the reflector may be spaced from that of the driven element in the second direction.

In an embodiment, the director may be the PIN diode having a third length in the first direction, spaced a second width from the driven element in a direction opposite to the second direction, and disposed parallel to the driven element, and a center of the director may be spaced apart from centers of the driven element and the reflector in the direction opposite to the second direction.

In an embodiment, the plurality of antenna areas may be eight antenna areas, and the eight antenna areas may be spaced by an angle of about 45° about an axis that passes a center point of the driven element in a third direction perpendicular to the first and second directions.

In an embodiment, the antenna structure may further include: an activation control unit configured to activate one antenna area among the plurality of antenna areas; and a feeding unit configured to feed radio frequency (RF) current to the driven element of the activated antenna area, and the activated antenna area may transmit/receive an electric wave progressed along a direction of a directivity of the activated antenna area.

In an embodiment, each of the first area of the driven element, the second area of the driven element, the reflector, and the director may include a plurality of PIN diodes, wherein the plurality of PIN diodes may be connected in series.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a plan view for explaining a Yagi-Uda antenna;

FIG. 2 is a plan view of the Yagi-Uda antenna according to an embodiment of the inventive concept;

FIG. 3 is cross-sectional views of the Yagi-Uda antennas taken along lines I-I′, II-II′, and III-III′ of FIG. 2 according to an embodiment of the inventive concept;

FIG. 4 is a block diagram for explaining an operation of the Yagi-Uda antenna according to an embodiment of the inventive concept;

FIG. 5 is a plan view of the Yagi-Uda antenna structure according to an embodiment of the inventive concept; and

FIG. 6 is a plan view of the Yagi-Uda antenna structure according to an embodiment of the inventive concept.

### DETAILED DESCRIPTION

Exemplary embodiments of the present invention will be described with reference to the accompanying drawings so as to sufficiently understand constitutions and effects of the present invention. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

In this specification, it will also be understood that when another component is referred to as being ‘on’ one component, it can be directly on the one component, or an intervening third component may also be present. Like reference numerals refer to like elements throughout.

The embodiment in the detailed description will be described with cross-sectional views and/or plan views as ideal exemplary views of the inventive concept. Also, in the figures, the dimensions of layers and areas are exaggerated for clarity of illustration. Areas exemplified in the drawings have general properties, and are used to illustrate a specific shape of a semiconductor package area. Thus, this should not be construed as limited to the scope of the present invention. Also, though terms like a first, a second, and a third are used to describe various areas and layers in various embodiments of the inventive concept, the areas and the layers are not limited to these terms. These terms are only used to distinguish one component from another component. An embodiment described and exemplified herein includes a complementary embodiment thereof.

In the following description, the technical terms are used only for explaining a specific exemplary embodiment while not limiting the present invention. The terms of a singular form may include plural forms unless referred to the contrary. The meaning of “include,” “comprise,” “including,” or “comprising,” specifies a property, a area, a fixed number, a step, a process, an element and/or a component but does not exclude other properties, areas, fixed numbers, steps, processes, elements and/or components.

Hereinafter, the present invention will be described in detail by explaining preferred embodiments of the invention with reference to the attached drawings.

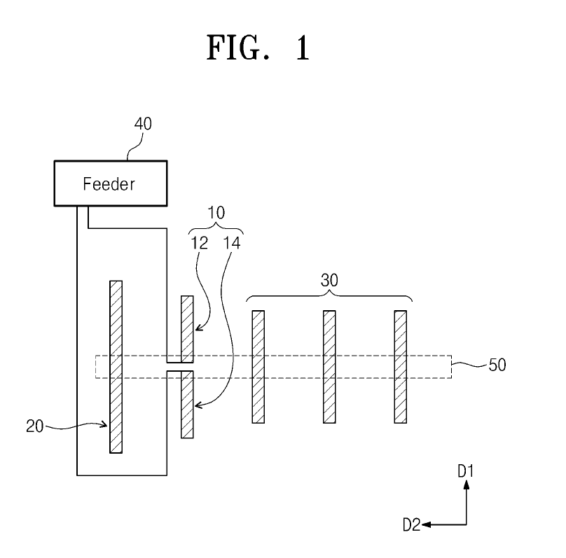

FIG. 1 is a plan view for explaining a Yagi-Uda antenna.

Referring to FIG. 1, a driven element 10 that is capable of transmitting/receiving an electric wave may be provided on a supporter 50. The driven element 10 may extend in a first direction D1. Although the driven element 10 is a half wave dipole, an embodiment of the inventive concept is not limited thereto. For example, the driven element 10 may have various types such as a loop type, a monopole type, and the like that are capable of transmitting/receiving an electric wave. The driven element 10 may have a first area 12 and a second area 14. The first area 12 and the second area 14 may be fed with current having polarities opposite to each other through a feeder 40. For example, the feeder 40 may apply (or feed) radio frequency (RF) alternating current to the first and second areas 12 and 14. When the first area 12 has a positive polarity, the second area 14 may have a negative polarity. On the contrary, when the first area 12 has the negative polarity, the second area 14 may have the positive polarity. The driven element 10 may be a metal.

A reflector 20 that is parallel to the driven element 10 may be provided on the supporter 50. The reflector 20 may have a center that is spaced apart from that of the driven element 10 in a second direction D2 crossing the first direction D1. A director 30 that is parallel to the driven element 10 may be provided on the supporter 50. The director 30 may have a center that is spaced apart from the centers of the reflector 20 and the driven element 10 in the second direction D2. The reflector 20 may be greater in length than the reflector 10. For example, the reflector 20 may reflect an electric wave that is transmitted by the reflector 10 toward the director 30. For another example, the reflector 20 may reflect an electric wave that is directed by the director 30 toward the driven element 10. The reflector 20 may be a metal.

The director 30 may be less in length than the driven element 10. The director 30 may allow an electric wave coming to the director 30 to have a directivity. For example, an electric wave that is transmitted by the driven element 10 may pass through the director 30 and then have the directivity toward a direction opposite to the second direction D2. An electric wave that is received by the driven element 10 may pass through the director 30, and then have the directivity toward the second direction D2.

Hereinafter, the Yagi-Uda antenna that is doped on a semiconductor substrate will be described.

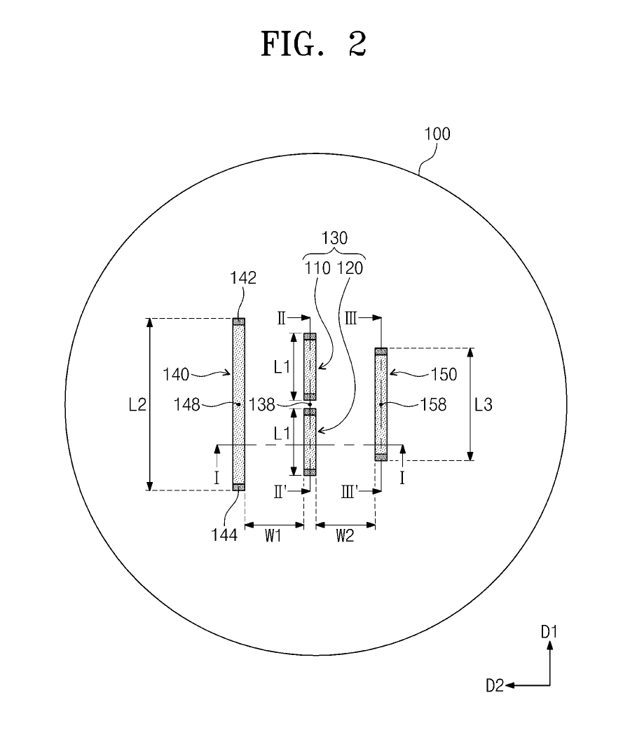

FIG. 2 is a plan view of the Yagi-Uda antenna according to an embodiment of the inventive concept.

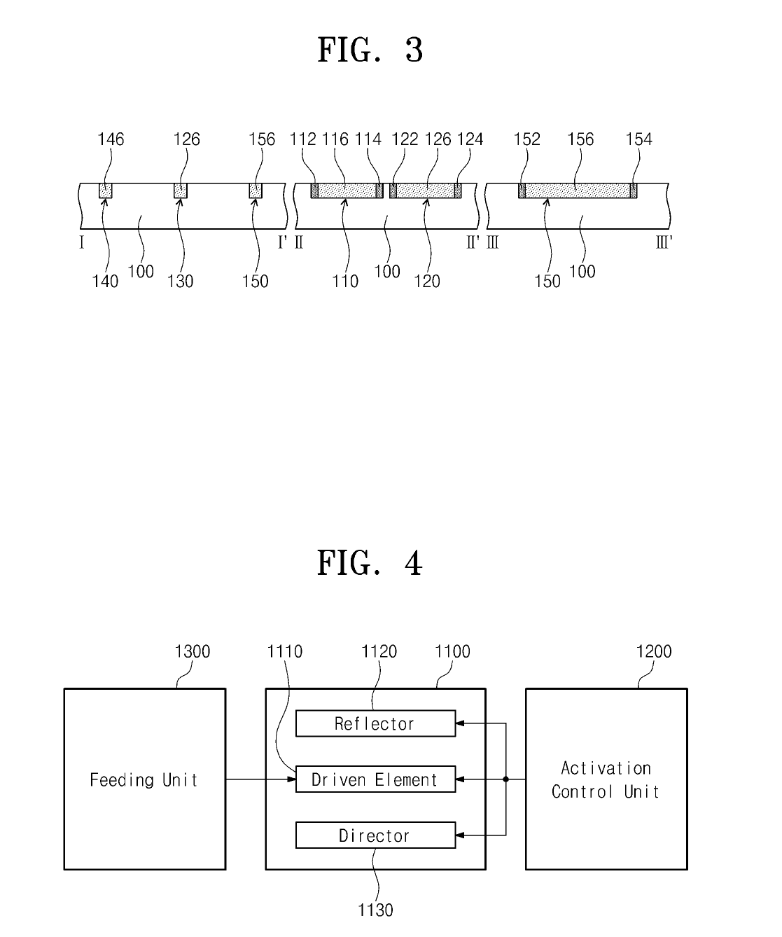

FIG. 3 is cross-sectional views of the Yagi-Uda antennas taken along lines I-I′, II-II′, and III-III′ of FIG. 2 according to an embodiment of the inventive concept.

Referring to FIGS. 2 and 3, a substrate 100 may be provided. The substrate 100 may be a semiconductor substrate. For example, the substrate 100 may include a single-element semiconductor such as, e.g., silicon (Si) and germanium (Ge) or a compound semiconductor such as, e.g., gallium arsenide (GaAs) and gallium phosphorus (GaP). The substrate 100 may have a plate shape. From a plane's perspective, although the substrate 100 has a circular shape, an embodiment of the inventive concept is not limited thereto. The substrate 100 may provide an area in which the Yagi-Uda antenna structure is provided.

A driven element 130, a reflector 140, and a director 150 may be provided on the substrate 100. The driven element 130, the reflector 140, and the director 150 may be solid state plasma cells. The solid state plasma cell may be in a solid state plasma state. The solid state plasma state may be a state in which a density of free electrons in a solid is high. For example, the solid state plasma cell may be a PIN diode cell. The PIN diode cell may have an active or inactive state. The active state may be a state in which a forward bias voltage is applied to the PIN diode cell. The activated PIN diode cell may have the free electrons having a high density therein. Accordingly, the PIN diode cell may have a state similar to metal with respect to the free electrons. The inactive state may be a state in which the bias voltage is not applied to the PIN diode cell, or a reverse bias voltage is applied thereto.

The driven element 130 may serve substantially the same as the driven element of the Yagi-Uda antenna that is described with reference to FIG. 1. The driven element 130 may transmit or receive an electric wave having a first wavelength. The driven element 130 may have a first area 110 and a second area 120. The first area 110 and the second area 120 may be fed with current through a feeding unit that will be described later. The feeding into the first and second areas 110 and 120 may be substantially the same as that described with reference to FIG. 1. Although the driven element 130 is a half wave dipole, an embodiment of the inventive concept is not limited thereto.

For example, the first area 110 may have a bar shape extending in a first direction D1 that is parallel to a top surface of the substrate 100. For example, the first area 110 may have a first length L1 in the first direction DE The first area 110 may include doped areas 112 and 114 on both side portions thereof in the first direction DE The first area 110 may include a genuine silicon area 116 disposed between the doped areas 112 and 114. The doped areas 112 and 114 may be doped in types different from each other. For example, when the first doped area 112 is doped in a P-type, the second doped area 114 may be doped in a N-type. For example, the doped areas 112 and 114 may be doped in the P-type or the N-type through an ion implantation process. In case of P-type doping, the doped areas 112 and 114 may be formed by ion-implanting group 3 elements (e.g., boron (B), aluminum (Al), indium (In), or gallium (Ga)) into a silicon (Si) substrate. In case of N-type doping, the doped areas 112 and 114 may be formed by ion-implanting group 5 elements (e.g., phosphorus (P), arsenic (As), antimony (Sb), or bismuth (Bi)) into the silicon (Si) substrate. When the forward bias voltage is applied to the first area 110 through an activation control unit (not shown) that will be described later, a density of free electrons of the genuine silicon area 116 may increase. In this case, the first area 110 may have a state similar to metal with related to the density of free electrons. Accordingly, the first area 110 may serve as a reflector together with the second area 120.

The second area 120 that is spaced apart from the first area in a direction opposite to the first direction D1 may be provided. The second area 120 may include doped areas 122 and 124 and a genuine silicon area 126 disposed between the doped areas 122 and 124. The second area 120 may have the same structure as that of the first area 110. For example, the sum of a length of the first area 110, a length of the second area 120, and a distance spaced between the first area 110 and the second area 120 may be the same as a half of a first wavelength of an electric wave that are transmitted/received by the driven element 130.

The reflector 140 may serve substantially the same as the reflector of the Yagi-Uda antenna that is described with reference to FIG. 1. The reflector 140 may reflect an electric wave having the first wavelength that is transmitted/received by the driven element 130. The electric wave reflection of the reflector 140 may be substantially the same as contents described with reference to FIG. 1. The reflector 140 may be spaced a first width W1 from the driven element 130 in the second direction D2 that is perpendicular to the first direction D1 and parallel to the top surface of the substrate 100. The reflector 140 may have a bar shape extending in the first direction D1. The reflector 140 may have a second length L2 in the first direction D1. For example, the second length L2 may be greater in length than the first wavelength. Accordingly, the reflector 140 may be greater in length than the driven element 130. The reflector 140 may be parallel to the driven element 130. The reflector 140 may have a center 148 that is spaced apart from a center 138 between the first and second areas 110 and 120 in the second direction D2. The reflector 140 may include doped areas 142 and 144 disposed on both end portions thereof in the first direction D1. The reflector 140 may include a genuine silicon area 146 disposed between the doped areas 142 and 144. Description for the doped areas 142 and 144 may be the same as that for the doped areas 112 and 114 of the first area 110 of the driven element 130. Accordingly, the reflector 140 may reflect an electric wave.

The director 150 may serve substantially the same as the director of the Yagi-Uda antenna that is described with reference to FIG. 1. The director 150 may direct an electric wave having the first wavelength that is transmitted/received by the driven element 130. The directed electric wave may have directionality (or directivity) in a constant direction. The electric wave direction of the director 150 may be substantially the same as contents described with reference to FIG. 1. The director 150 may be spaced a second width W2 in a direction opposite to the second direction D2. The director 150 may have a bar shape extending in the first direction D1. The director 150 may have a third length L3 in the first direction D1. For example, the third length L3 may be less in length than the first wavelength. Accordingly, the director 150 may be less in length than the driven element 130. The director 150 may be parallel to the driven element 130. The director 150 may have a center 158 that is spaced apart from a center 138 between the first and second areas 110 and 120 and a center 148 of the reflector 140 in the second direction D2. The director 150 may include doped areas 152 and 154 disposed on both end portions thereof in the first direction D1. The director 150 may include a genuine silicon area 156 disposed between the doped areas 152 and 154. Description for the doped areas 152 and 154 may be the same as that for the doped areas 112 and 114 of the first area 110 of the driven element 130. Accordingly, the director 150 may direct an electric wave.

Although each of the driven element 130, the reflector 140, and the director 150 is illustrated as one PIN diode, on the contrary to this, each of the driven element 130, the reflector 140, and the director 150 may include a plurality of PIN diodes. Also, each of the first and second areas 110 and 120 that constitute the driven element 130 may include a plurality of PIN diodes. In an embodiment, the PIN diodes may be connected in series.

According to an embodiment of the inventive concept, the driven element 130, the reflector 140, and the director 150 that are formed by doping an upper portion of the substrate 100 may be provided. It may be unnecessary to provide a separate structure on the substrate 100 to form the Yagi-Uda antenna. Accordingly, the Yagi-Uda antenna in which a manufacturing process is simplified and manufacturing costs are reduced may be provided.

FIG. 4 is a block diagram for explaining an operation of the Yagi-Uda antenna according to an embodiment of the inventive concept. For simplicity of description, description for contents that are substantially the same as those of the Yagi-Uda antenna structure that is described with reference to FIGS. 2 and 3 will not be provided.

Referring to FIG. 4, an antenna structure 1100 may be provided. The antenna structure 1100 may include a driven element 1110, a reflector 1120, and a director 1130. Each of the driven element 1110, reflector 1120, and director 1130 of the antenna structure 1100 may be substantially the same as the driven element 130, reflector 140, and director 150 of the Yagi-Uda antenna structure that is described with reference to FIGS. 2 and 3.

An activation control unit 1200 for activating the driven element 1110, reflector 1120, and director 1130 of the antenna structure 1100 may be connected to the driven element 1110, reflector 1120, and director 1130 of the antenna structure 1100. The activation control unit 1200 may apply a forward bias voltage to the driven element 1110, the reflector 1120, and the director 1130. For example, the activation control unit 1200 may apply a positive (+) voltage to a P-doped area of the driven element 1110, the reflector 1120, and the director 1130, and a negative (−) voltage to a N-doped area of the driven element 1110, the reflector 1120, and the director 1130. Accordingly, the driven element 1110, the reflector 1120, and the director 1130 may be activated. The driven element 1110, the reflector 1120, and the director 1130, which are activated, may have a high free-electron density.

A feeding unit 1300 that feeds current to first and second areas (not shown) of the driven element 1110 may be provided. For example, the feeding unit 1300 may apply a radio frequency (RF) voltage (or current) to the first and second areas. The RF voltage may have a frequency that is the same as that of an electric wave that is transmitted/received by the driven element 1110. Accordingly, the Yagi-Uda antenna structure according to an embodiment of the inventive concept may transmit/receive the electric wave.

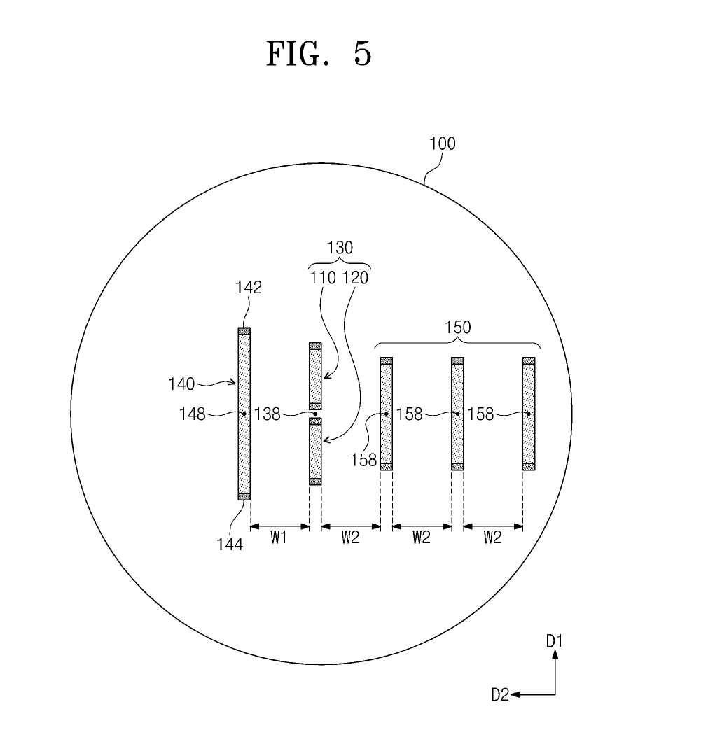

FIG. 5 is a plan view of the Yagi-Uda antenna structure according to an embodiment of the inventive concept. For simplicity of description, description for contents that are substantially the same as those of the Yagi-Uda antenna structure that is described with reference to FIGS. 2 and 3 will not be provided.

Referring to FIG. 5, a driven element 130, a reflector 140, and a director 150 may be provided on a substrate 100. The driven element 130 and the reflector 140 may be substantially the same as the driven element 130 and the reflector 140, which are described with reference to FIGS. 2 and 3. The director 150 may be substantially the same as that described with reference to FIGS. 2 and 3, except for the number and position of the director 150.

The director 150 may be provided in plurality. For example, three directors 150 that are parallel to each other may be provided on the substrate 100. The directors 150 may have centers 158 that are spaced apart from the centers 138 and 148 of the driven element 130 and the reflector 140 in a direction opposite to the second direction D2. The director 150 that is the most adjacent to the driven element 130 may be spaced a second width W2 from the driven element 130 in a direction opposite to the second direction D2. The directors 150 may be spaced the second width W2 from each other in the second direction D2. For example, the second width W2 may have a quarter of a wavelength of an electric wave that is transmitted/received by the driven element part 130. When the number of the director 150 increases, a directivity of the transmitted/received electric wave may increase. Accordingly, the directivity of the electric wave that is transmitted/received by the driven element 130 through a plurality of directors 150 may increase. Accordingly, the Yagi-Uda antenna structure that formed by doping the substrate 100 may be provided.

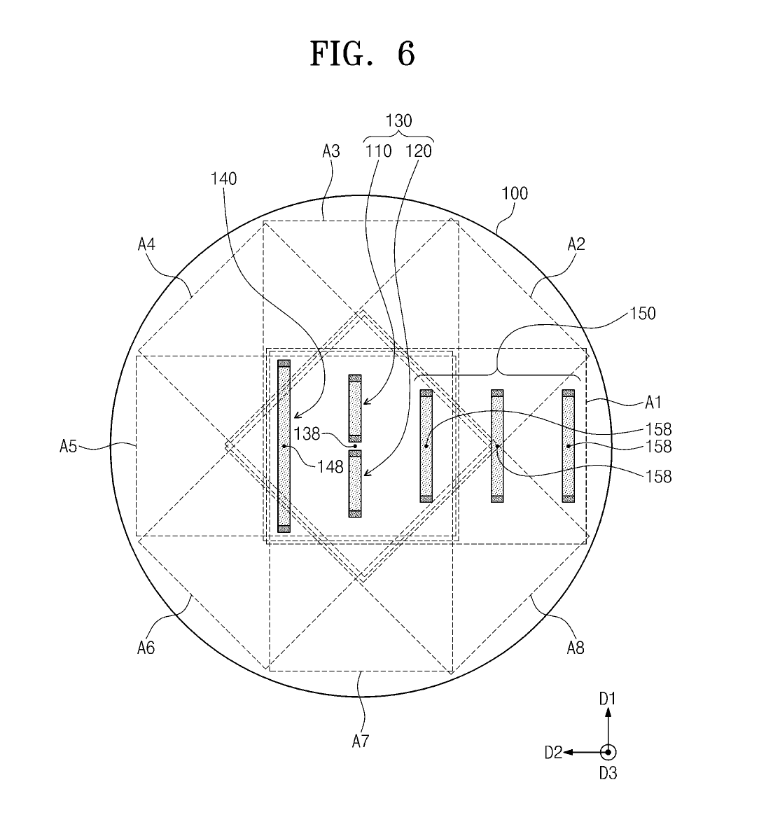

FIG. 6 is a plan view of the Yagi-Uda antenna structure according to an embodiment of the inventive concept. For simplicity of description, description for contents that are substantially the same as those of the Yagi-Uda antenna structure that is described with reference to FIGS. 2 and 5 will not be provided.

Referring to FIG. 6, the plurality of Yagi-Uda antennas A1 to A8 may be provided on the substrate 100. For simplicity of description, a driven element 130, a reflector 140, and a director 150 are illustrated for only a first Yagi-Uda antenna A1 among the plurality of Yagi-Uda antennas A1 to A8. Although the eight Yagi-Uda antennas A1 to A8 are illustrated, the number of the Yagi-Uda antennas A1 to A8 is not limited thereto. Each of the Yagi-Uda antennas A1 to A8 may be substantially the same as the Yagi-Uda antenna structures that are described with reference to FIGS. 2, 3, and 5. The plurality of Yagi-Uda antennas A1 to A8 may have directivities different from each other. For example, the eight Yagi-Uda antenna areas A1 to A8 may be spaced by an angle of about 45° from each other about an axis that passes a center point 138 of the driven element 130 in a third direction D3 perpendicular to the first and second directions D1 and D2.

One Yagi-Uda antenna among the plurality of Yagi-Uda antennas A1 to A8 may be activated at a time. The activated Yagi-Uda antenna A1 may transmit/receive an electric wave. Meanwhile, the inactivated Yagi-Uda antennas A2 to A8 may not transmit/receive the electric wave. The Yagi-Uda antennas A2 to A8 expressed by a dotted line may be in an inactive state. The activated Yagi-Uda antenna A1 including hatching may be in an active state. The Yagi-Uda antennas A1 to A8 may be activated through the activation control unit 1200 that is described with reference to FIG. 4. For example, the driven element 130, the reflector 140, and the director 150 may be applied a forward bias voltage through the activation control unit 1200. Accordingly, the Yagi-Uda antenna A1 having the directivity to a specific direction may be activated.

According to the current embodiment of the inventive concept, the Yagi-Uda antenna structure that is formed by doping the upper portion of the substrate may be provided. Accordingly, the state, radiation direction, gain, and the like of the Yagi-Uda antenna may be adjusted.

However, the effects of the current embodiment of the inventive concept are not limited to the above-described disclosure.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. An antenna structure comprising:
a substrate; and
a driven element, a reflector, and a director, which are disposed on the substrate and respectively configured to transmit/receive, reflect, and direct an electric wave having a first wavelength,
wherein the driven element comprises:
a first area having a first length in a first direction parallel to a top surface of the substrate; and
a second area having the first length in the first direction, the second area being spaced apart from the first area in the first direction, and
each of the first area and the second area is at least one PIN diode that is formed by doping an upper portion of the substrate.

2. The antenna structure of claim 1, wherein the sum of the length of the first area, the length of the second area, and a distance spaced between the first and second areas is equal to a half of the first wavelength.

3. The antenna structure of claim 1, wherein the reflector is a PIN diode having a second length in the first direction, spaced a first width from the driven element in a second direction perpendicular to the first direction, and disposed parallel to the driven element, and
a center of the reflector is spaced apart from that of the driven element in the second direction.

4. The antenna structure of claim 3, wherein the second length is greater than a half of the first wavelength.

5. The antenna structure of claim 3, wherein the director is a PIN diode having a third length in the first direction, spaced a second width from the driven element in a direction opposite to the second direction, and disposed parallel to the driven element, and
a center of the director is spaced apart from centers of the driven element and the reflector in the direction opposite to the second direction.

6. The antenna structure of claim 5, wherein the third length is equal to or less than a half of the first wavelength.

7. The antenna structure of claim 5, wherein the first width is equal to the second width.

8. The antenna structure of claim 5, wherein each of the first width and the second width is equal to a quarter of the first wavelength.

9. The antenna structure of claim 5, further comprising a plurality of PIN diodes spaced the second width from the director in the direction opposite to the second direction and each of which has the third length in the first direction,
wherein the plurality of PIN diodes are spaced the second width from each other in the direction opposite to the second direction.

10. The antenna structure of claim 9, wherein the plurality of PIN diodes are three PIN diodes.

11. The antenna structure of claim 9, wherein the second width is equal to a quarter of the first wavelength.

12. An antenna structure comprising:
a substrate; and
a plurality of antenna areas provided on the substrate and having directivities different from each other,
wherein each of the antenna areas comprises:
a driven element, a reflector, and a director, which are provided on the substrate and respectively configured to transmit/receive, reflect, and direct an electric wave having a first wavelength, and
the driven element comprises:
a first area having a first length in a first direction parallel to a top surface of the substrate; and
a second area having the first length in the first direction, the second area being spaced from the first area in the first direction, and
each of the first area and the second area is at least one PIN diode that is formed by doping an upper portion of the substrate.

13. The antenna structure of claim 12, wherein the reflector is the PIN diode having a second length in the first direction, spaced a first width from the driven element in a second direction perpendicular to the first direction, and disposed parallel to the driven element, and
a center of the reflector is spaced from that of the driven element in the second direction.

14. The antenna structure of claim 13, wherein the director is the PIN diode having a third length in the first direction, spaced a second width from the driven element in a direction opposite to the second direction, and disposed parallel to the driven element, and
a center of the director is spaced apart from centers of the driven element and the reflector in the direction opposite to the second direction.

15. The antenna structure of claim 14, wherein the plurality of antenna areas are eight antenna areas, and
the eight antenna areas are spaced by an angle of about 45° about an axis that passes a center point of the driven element in a third direction perpendicular to the first and second directions.

16. The antenna structure of claim 12, further comprising:
an activation control unit configured to activate one antenna area among the plurality of antenna areas; and
a feeding unit configured to feed radio frequency (RF) current to the driven element of the activated antenna area,
wherein the activated antenna area transmits/receives an electric wave progressed along a direction of a directivity of the activated antenna area.

17. The antenna structure of claim 12, wherein each of the first area of the driven element, the second area of the driven element, the reflector, and the director includes a plurality of PIN diodes,
wherein the plurality of PIN diodes are connected in series.

18. The antenna structure of claim 1, wherein each of the first area of the driven element, the second area of the driven element, the reflector, and the director includes a plurality of PIN diodes,
wherein the plurality of PIN diodes are connected in series.
